(19) United States
(12) Patent Application Publication
(10) Pub. No.: US 2025/0309067 A1
(43) Pub. Date: Oct. 2, 2025

(54) SEMICONDUCTOR DEVICE AND MANUFACTURING METHOD THEREOF

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Kyo TANABIKI, Himeji (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/825,302

(22) Filed: Sep. 5, 2024

(30) Foreign Application Priority Data
Apr. 2, 2024 (JP) 2024-059544

(51) Int. Cl. H01L 23/495; H01L 21/48; H01L 21/56; H01L 23/00; H01L 23/31

(52) U.S. Cl. CPC H01L 23/49541; H01L 21/4842; H01L 24/40; H01L 24/41; H01L 21/56; H01L 23/3107; H01L 24/32; H01L 24/73; H01L 2224/32245; H01L 2224/40175; H01L 2224/4103; H01L 2224/41051; H01L 2224/73263

(57) ABSTRACT

According to one embodiment, a semiconductor device includes a lead frame, a semiconductor chip, a lead terminal and a package. The package includes an upper surface, a lower surface, and first and second side surfaces between the upper surface and the lower surface. The first side surface has a first surface, a second surface and a third surface. The first surface is continuous with the upper surface and is provided in an oblique direction with respect to the upper surface. The second surface is continuous with the first surface and is provided in a direction parallel to the upper surface. The third surface is continuous with the second surface and is provided in a direction orthogonal to the upper surface. The lead terminal protrudes from the first side surface and does not protrude from the second side surface.

### CROSS-REFERENCE TO RELATED APPLICATION

This application is based upon and claims the benefit of priority from Japanese Patent Application No. 2024-059544, filed Apr. 2, 2024, the entire contents of which are incorporated herein by reference.

### FIELD

Embodiments described herein relate generally to a semiconductor device and a manufacturing method thereof.

### BACKGROUND

A semiconductor device including a semiconductor package in which a semiconductor chip is mounted is known.

### BRIEF DESCRIPTION OF DRAWINGS

FIG. 1 is a perspective view illustrating the outer shape of a semiconductor device according to an embodiment.

FIG. 2 is an upper surface view of the semiconductor device according to the embodiment.

FIG. 3 is a first side surface view of the semiconductor device according to the embodiment.

FIG. 4 is a second side surface view of the semiconductor device according to the embodiment.

FIG. 5 is an enlarged view of the portion A in the semiconductor device illustrated in FIG. 3.

FIG. 6 is an enlarged view of the portion B in the semiconductor device illustrated in FIG. 4.

FIG. 7 is an upper surface view illustrating the structure in the package of the semiconductor device according to the embodiment.

FIG. 8 is a cross-sectional view of the semiconductor device illustrated in FIG. 7 taken along the line VIII-VIII.

FIG. 9 is a cross-sectional view of the semiconductor device illustrated in FIG. 7 taken along the line IX-IX.

FIG. 10 is a cross-sectional view of the semiconductor device illustrated in FIG. 7 taken along the line X-X.

FIG. 11 is a flowchart outlining a method of manufacturing the semiconductor device according to the embodiment.

FIG. 12 is a plan view of a lead frame prepared in a manufacturing process of the semiconductor device according to the embodiment.

FIGS. 13 to 18 are an upper surface view and a cross-sectional view in the manufacturing process of the semiconductor device according to the embodiment.

FIG. 19 is a view illustrating the arrangement of a part of a mold in the manufacturing process of the semiconductor device according to the embodiment.

FIGS. 20 and 21 are a view illustrating the size of a package and a lead terminal in the semiconductor device according to the embodiment.

FIG. 22 is a first side surface view of a semiconductor device according to a modification of the embodiment.

FIG. 23 is a second side surface view of the semiconductor device according to the modification of the embodiment.

FIG. 24 is an enlarged view of the portion C in the semiconductor device illustrated in FIG. 23.

### DETAILED DESCRIPTION

In general, according to one embodiment, a semiconductor device includes a lead frame, a semiconductor chip, a first lead terminal and a package.

The semiconductor chip is provided above the lead frame.

The first lead terminal is electrically connected to the semiconductor chip. The package encapsulates the semiconductor chip, a part of the lead frame, and a part of the first lead terminal. The package includes an upper surface, a lower surface, a first side surface, and a second side surface. The upper surface is provided above the semiconductor chip. The lower surface is provided below the semiconductor chip. The first side surface is provided between the upper surface and the lower surface, and the first lead terminal protrudes from the first side surface. The first side surface has a first surface, a second surface, and a third surface. The first surface is continuous with the upper surface of the package and is provided in an oblique direction with respect to the upper surface of the package. The second surface is continuous with the first surface and is provided in a direction parallel to the upper surface of the package. The third surface is continuous with the second surface and is provided in a direction orthogonal to the upper surface of the package. The second side surface is provided between the upper surface and the lower surface, and the first lead terminal does not protrude from the second side surface.

Hereinafter, an embodiment will be described with reference to the drawings. In the following description, components having the same function and configuration are denoted by the same reference numerals. In addition, the following embodiment exemplifies an apparatus and a method for embodying the technical idea of this embodiment, and does not specify the material, shape, structure, arrangement, and the like of the components as follows.

### 1. EMBODIMENT

### 1.1 Configuration of Semiconductor Device

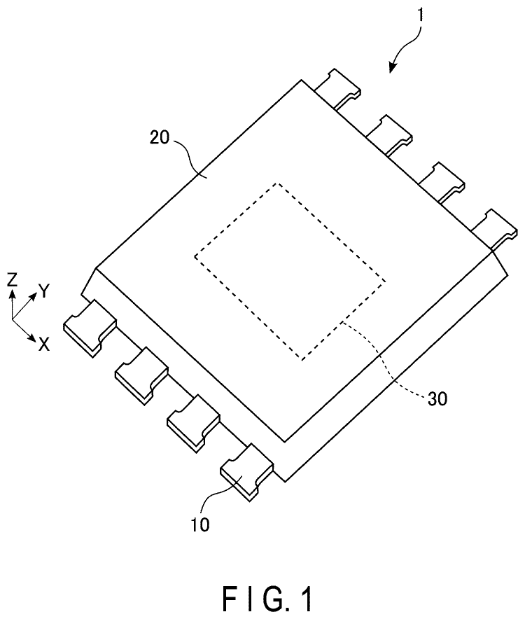

A semiconductor device 1 according to the embodiment will be described. FIG. 1 is a perspective view illustrating the outer shape of the semiconductor device 1 according to the embodiment. In FIG. 1 and the subsequent figures, the direction parallel to the upper surface of a package 20 is referred to as the X direction, the direction parallel to the upper surface of the package 20 and orthogonal to the X direction is referred to as the Y direction, and the direction orthogonal to the upper surface of the package 20 (alternatively, the XY plane) is referred to as the Z direction.

The semiconductor device 1 includes a semiconductor package, and includes, for example, a surface mount small outline package (SOP) that can be mounted on a mounting surface of a printed circuit board. The semiconductor device 1 includes lead terminals (alternatively, a lead frame) 10, a package 20, and a semiconductor chip (alternatively, a semiconductor element) 30.

The lead terminals 10 are electrically connected to the electrode of the semiconductor chip 30. The lead terminals 10 also serve as terminals for connection to the outside, and are connected to, for example, a circuit provided on a printed circuit board. The lead terminal 10 may be a part of the lead frame protruding from the package 20.

The package 20 encapsulates the semiconductor chip 30, a part of the lead terminals 10, and a part of the lead frame. That is, the package 20 seals the semiconductor chip 30, a part of the lead terminals 10, and a part of the lead frame. The package 20 protects the semiconductor chip 30 from the external environment, and further fixes the lead terminals 10, the lead frame, and the semiconductor chip 30.

The semiconductor chip 30 includes, for example, a MOS field-effect transistor, and has a source, a drain, and a gate.

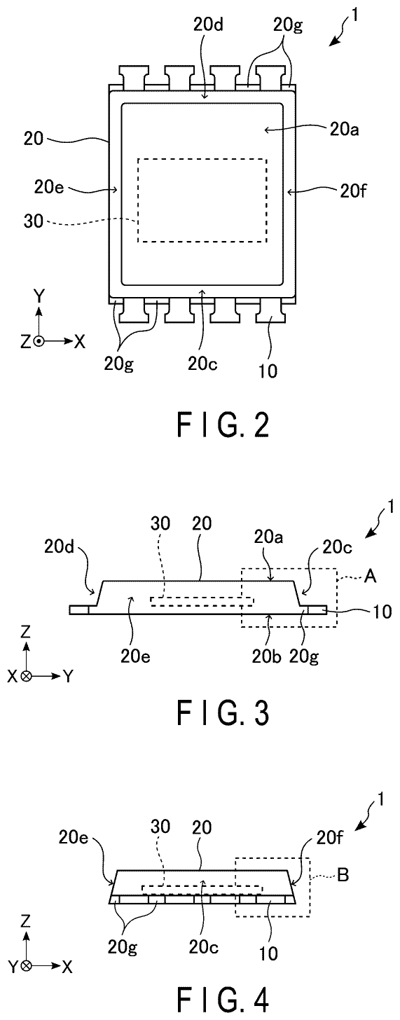

Next, details of the outer shape of the semiconductor device 1 according to the embodiment will be described. FIG. 2 is an upper surface view of the semiconductor device 1 according to the embodiment. FIG. 3 is a first side surface view of the semiconductor device 1, and FIG. 4 is a second side surface view of the semiconductor device 1. FIG. 2 is a view of the semiconductor device 1 as viewed from the Z direction, that is, from above the package 20 (alternatively, the upper surface). FIG. 3 is a view of the semiconductor device 1 as viewed from the X direction, and FIG. 4 is a view of the semiconductor device 1 as viewed from the Y direction.

As illustrated in FIGS. 2, 3, and 4, the package 20 of the semiconductor device 1 has, for example, a substantially hexahedral shape, and has an upper surface 20a, a lower surface 20b, and four side surfaces 20c, 20d, 20e, and 20f.

The upper surface 20a of the package 20 is provided above the semiconductor chip 30. The lower surface 20b of the package 20 is provided below the semiconductor chip 30. The upper surface 20a and the lower surface 20b are orthogonal to the Z direction and face each other.

The side surfaces 20c and 20d of the package 20 are provided between the upper surface 20a and the lower surface 20b. The side surfaces 20c and 20d are orthogonal to the Y direction, in other words, along the X direction. The side surfaces 20c and 20d face each other. As illustrated in FIGS. 2 and 3, the lead terminals 10 protrude from the side surfaces 20c and 20d. Burrs 20g, which are a part of the package 20, is provided in a portion of the side surfaces 20c and 20d from which the lead terminal 10 does not protrude.

The side surface 20c is provided with the lead terminals 10 and the burrs 20g. The lead terminals 10 are arranged at predetermined intervals in the X direction. The burrs 20g are provided adjacent to the lead terminals 10 on the side surface 20c. The burrs 20g are provided between the lead terminals 10.

Similarly, the side surface 20d is provided with the lead terminals 10 and the burrs 20g. The lead terminals 10 are arranged at predetermined intervals in the X direction. The burrs 20g are provided adjacent to the lead terminal 10 on the side surface 20d, and are further provided between the lead terminals 10.

The side surfaces 20e and 20f of the package 20 are provided between the upper surface 20a and the lower surface 20b. The side surfaces 20e and 20f are orthogonal to the X direction, in other words, along the Y direction. The side surfaces 20e and 20f face each other. As illustrated in FIGS. 2 and 4, the lead terminals 10 do not protrude from the side surfaces 20e and 20f, and the burrs 20g are not provided, either.

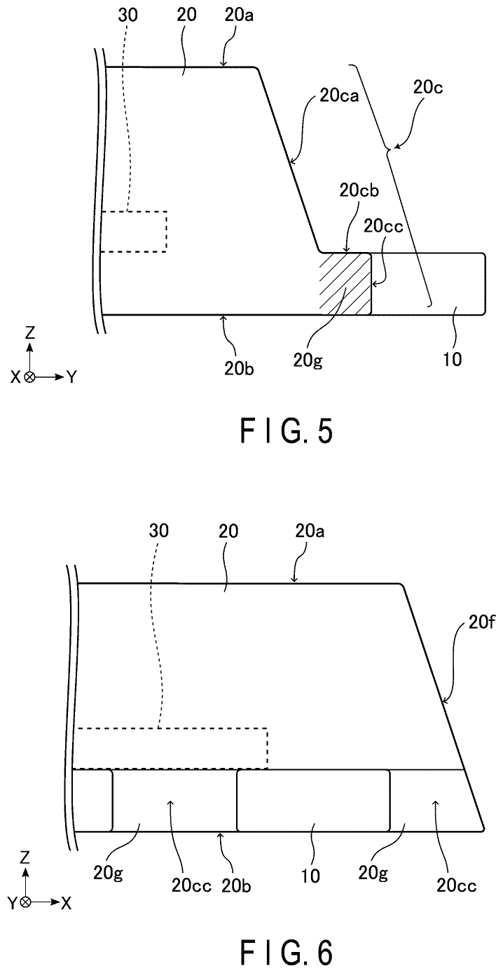

Next, details of the side surfaces 20c, 20d, 20e, and 20f of the package 20 will be described. FIG. 5 is an enlarged view of the portion A in the semiconductor device 1 illustrated in FIG. 3, and illustrates the detailed structure of the side surface 20c. Since the structure of the side surface 20d is similar to that of the side surface 20c, description thereof is omitted.

As described above, the lead terminals 10 protrude from the side surface 20c of the package 20. The burrs 20g protrude from the side surface 20c on both sides of the lead terminal 10. The burrs 20g protrude on the side surface 20c and are provided adjacent to the lead terminal 10.

The side surface 20c of the package 20 has a surface 20ca, a surface 20cb, and a surface 20cc. The surface 20ca is continuous with the upper surface 20a of the package 20 and is provided in an oblique direction with respect to the upper surface 20a of the package 20. The surface 20cb is continuous with the surface 20ca and is provided in the direction parallel to the upper surface 20a of the package 20. The surface 20cc is continuous with the surface 20cb and is provided in the direction orthogonal to the upper surface 20a of the package 20. The surface 20cb is the upper surface of the burr 20g, and the surface 20cc is the side surface of the burr 20g. For example, the lower surface 20b of the package 20 is substantially the same as the lower surface of the burr 20g.

In the Z direction, the position of the upper surface 20cb of the burr 20g coincides with the position of the upper surface of the lead terminal 10. In other words, the distance from the lower surface 20b of the package 20 to the upper surface 20cb of the burr 20g coincides with the distance from the lower surface 20b of the package 20 to the upper surface of the lead terminal 10. In the Z direction, the position of the lower surface 20b of the burr 20g coincides with the position of the lower surface of the lead terminal 10.

FIG. 6 is an enlarged view of the portion B in the semiconductor device 1 illustrated in FIG. 4, and illustrates the detailed structure of the side surface 20f. Since the structure of the side surface 20e is similar to that of the side surface 20f, description thereof is omitted.

As described above, the lead terminals 10 do not protrude from the side surface 20f of the package 20. Furthermore, no burrs 20g are provided on the side surface 20f of the package 20.

The side surface 20f of the package 20 is provided in an oblique direction with respect to the upper surface 20a of the package 20.

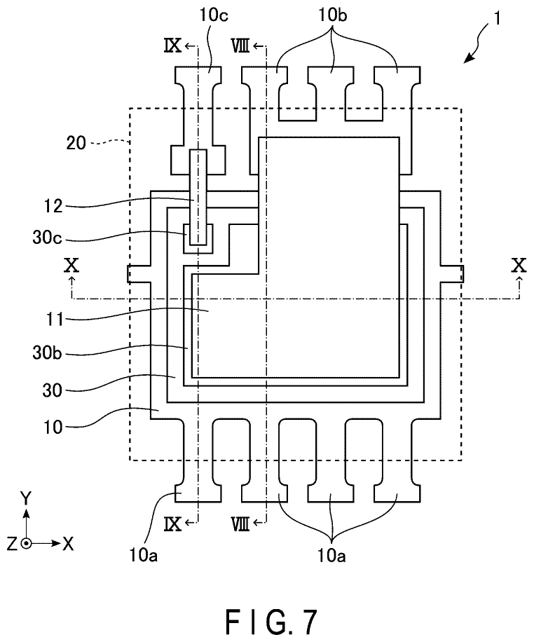

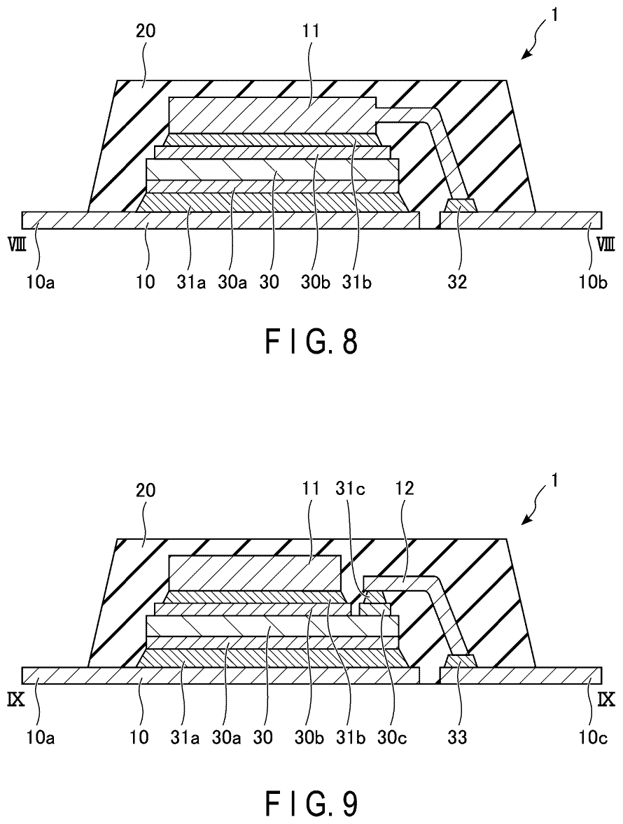

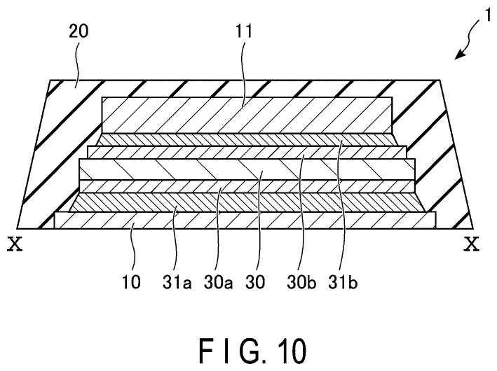

Next, the structure in the package 20 of the semiconductor device 1 according to the embodiment will be described. FIG. 7 is an upper surface view illustrating the structure in the package 20 of the semiconductor device 1 according to the embodiment. FIG. 8 is a cross-sectional view of the semiconductor device 1 illustrated in FIG. 7 taken along the line VIII-VIII. FIG. 9 is a cross-sectional view of the semiconductor device 1 illustrated in FIG. 7 taken along the line IX-IX. FIG. 10 is a cross-sectional view of the semiconductor device 1 illustrated in FIG. 7 taken along the line X-X. FIG. 7 is a view of the semiconductor device 1 as seen through the package 20 from above (that is, from the Z direction). In FIG. 7, the package 20 is indicated by a broken line. In FIGS. 7, 8, and 9, the lead terminals 10 is represented by 10a, 10b, and 10c according to the position where the lead terminals 10 are provided.

As illustrated in FIGS. 7 to 10, the semiconductor device 1 includes a lead frame 10 including lead terminals 10a, lead terminals 10b, a lead terminal 10c, a conductor layer 11, a conductor layer 12, a package 20, a semiconductor chip 30, a drain electrode layer 30a, a source electrode layer 30b, a gate electrode layer 30c, a bonding layer 31a, a bonding layer 31b, a bonding layer 31c, a bonding layer 32, and a bonding layer 33.

As illustrated in FIGS. 7 and 8, the bonding layer 31a is provided on the lead frame 10. The drain electrode layer 30a is provided on the bonding layer 31a. The semiconductor chip 30 is provided on the drain electrode layer 30a. The source electrode layer 30b is provided on the semiconductor chip 30. The bonding layer 31b is provided on the source electrode layer 30b. The bonding layer 32 is provided on the lead terminals 10b. Further, the conductor layer 11 is provided on the bonding layers 31b and 32.

As illustrated in FIGS. 7 and 9, the gate electrode layer 30c is provided on the semiconductor chip 30. The bonding layer 31c is provided on the gate electrode layer 30c. The bonding layer 33 is provided on the lead terminal 10c. Further, the conductor layer 12 is provided on the bonding layers 31c and 33.

That is, as illustrated in FIGS. 7 to 10, the semiconductor chip 30 is provided on the lead frame 10 via the bonding layer 31a and the drain electrode layer 30a. On the semiconductor chip 30, the conductor layer 11 is provided via the source electrode layer 30b and the bonding layer 31b. On the lead terminals 10b, a part of the conductor layer 11 is provided via the bonding layer 32. On the semiconductor chip 30, the conductor layer 12 is provided via the gate electrode layer 30c and the bonding layer 31c. On the lead terminal 10c, a part of the conductor layer 12 is provided via the bonding layer 33.

The lead terminals 10a, 10b, and 10c of the semiconductor device 1 having the above structure are connected to the semiconductor chip 30 as follows.

The semiconductor chip 30 includes, for example, a MOS field-effect transistor, and has a drain, a source, and a gate.

The lead terminals 10a are electrically connected to the drain of the semiconductor chip 30 via the bonding layer 31a and the drain electrode layer 30a. The lead terminals 10b are electrically connected to the source of the semiconductor chip 30 via the bonding layer 32, the conductor layer 11, the bonding layer 31b, and the source electrode layer 30b. Further, the lead terminal 10c is electrically connected to the gate of the semiconductor chip 30 via the bonding layer 33, the conductor layer 12, the bonding layer 31c, and the gate electrode layer 30c.

Next, the materials of the members constituting the semiconductor device 1 according to the embodiment will be described.

The lead terminals (and the lead frame) 10 include a conductive member, and include, for example, a metal such as copper or aluminum. The conductor layers 11 and 12 include a conductive member, and include, for example, a metal such as copper or aluminum. The package 20 includes an insulator, for example, insulating resins or ceramics. The burrs 20g are a part of the package 20, and includes an insulator, for example, insulating resins or ceramics, similarly to the package 20. The thickness of each of the burrs 20g is equal to the thickness of each of the lead terminals (alternatively, the lead frame) 10. That is, the thickness of each of the burrs 20g in the Z direction is substantially equal to the thickness of each of the lead terminals (alternatively, the lead frame) 10 in the Z direction.

The semiconductor chip 30 includes, for example, a MOS field-effect transistor or an insulated gate bipolar transistor (IGBT). The semiconductor chip 30 includes, for example, silicon (Si), silicon carbide (Sic), gallium nitride (GaN), or gallium arsenide (GaAs) as a semiconductor material.

The drain electrode layer 30a, the source electrode layer 30b, and the gate electrode layer 30c include, for example, a metal such as aluminum. The bonding layers 31a, 31b, 31c, 32, and 33 include a metal such as copper, silver, or tin.

### 1.2 Method of Manufacturing Semiconductor Device

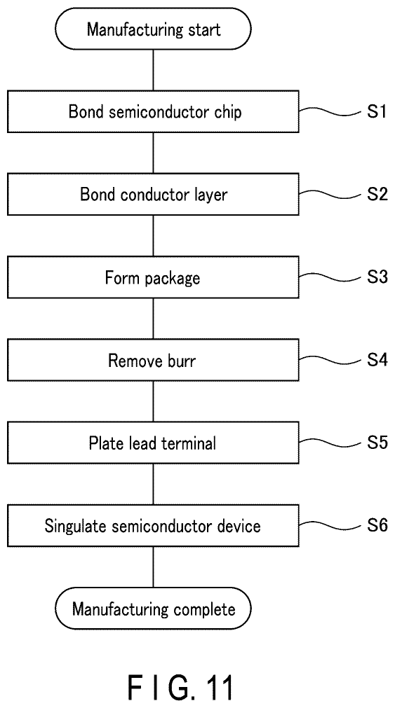

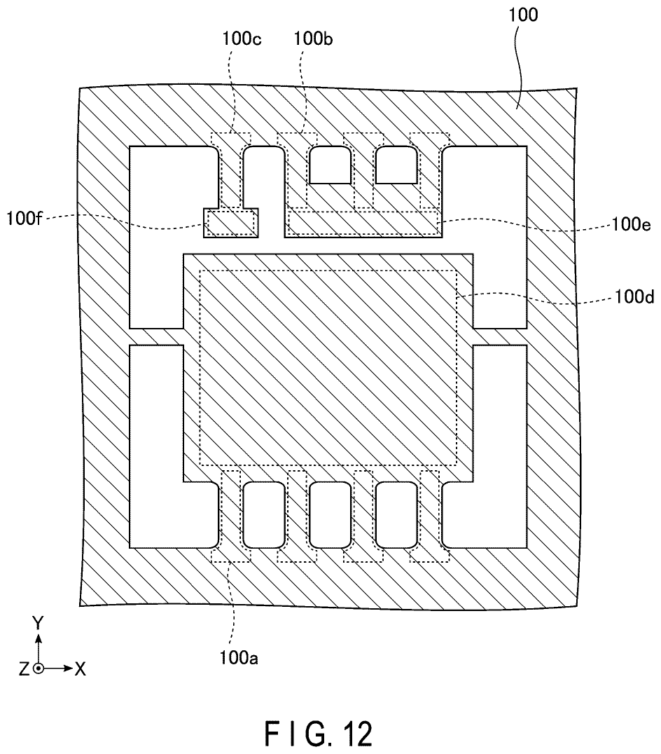

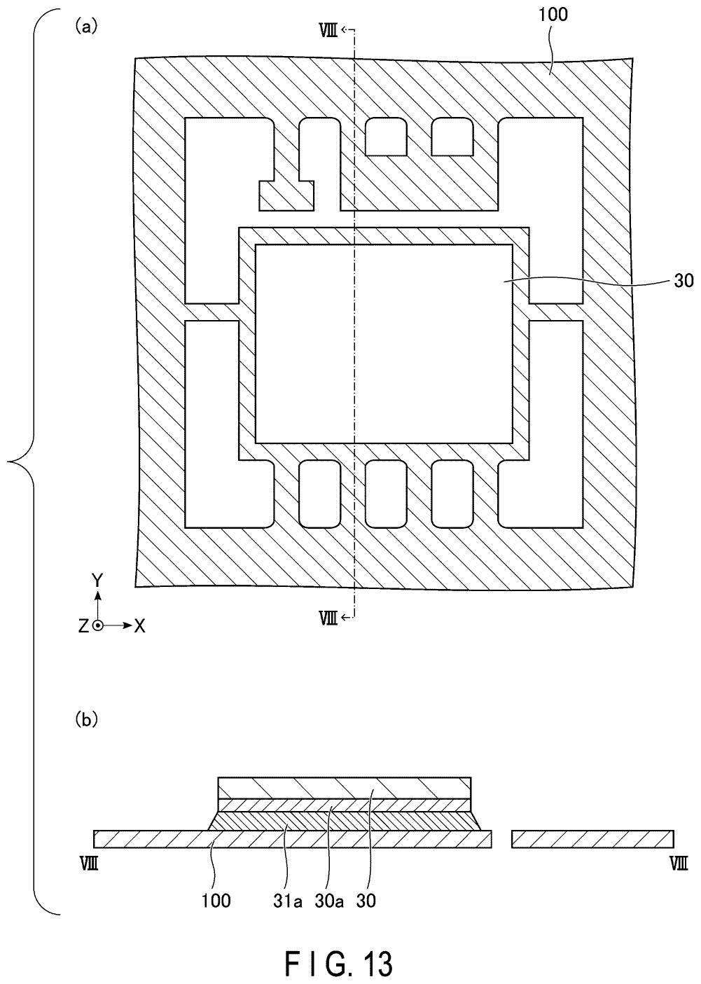

Next, the method of manufacturing the semiconductor device 1 according to the embodiment will be described. FIG. 11 is a flowchart outlining the method of manufacturing the semiconductor device 1 according to the embodiment. FIG. 12 is a plan view of a lead frame prepared in the manufacturing process of the semiconductor device 1. FIGS. 13 to 18 are upper surface views and cross-sectional views in the manufacturing process of the semiconductor device 1. FIG. 12 is a view of a lead frame 100 as viewed from above (that is, in the Z direction). In each of FIGS. 13 to 18, the view indicated as (a) is a view of the lead frame 100 as viewed from above, and the view indicated as (b) illustrates the cross section taken along the line VIII-VIII in (a).

In the manufacturing process of the semiconductor device 1, the lead frame 100 as illustrated in FIG. 12 is prepared. The lead frame 100 shows the state before the semiconductor chip 30 is bonded. The lead frame 100 includes portions 100a, 100b, and 100c serving as the lead terminal, a portion 100d to which the semiconductor chip 30 is bonded, and portions 100e and 100f to which the conductor layers 11 and 12 are bonded. Here, FIG. 12 illustrates a lead frame 100 to which a semiconductor chip 30 is bonded. However, in the manufacturing process, for example, a strip-shaped frame in which a plurality of lead frames 100 is arranged is prepared. Then, a plurality of semiconductor chips 30 is bonded to the lead frames 100 each, and a plurality of semiconductor devices 1 is manufactured through other steps. Thereafter, the semiconductor devices 1 are cut and singulated into individual semiconductor devices 1.

The semiconductor device 1 is manufactured by, for example, the following steps.

First, as illustrated in FIGS. 11 and 13, the semiconductor chip 30 is bonded (alternatively, placed) above the lead frame 100 (S1). Specifically, the bonding layer 31a and the drain electrode layer 30a are formed on the lead frame 100. Further, the semiconductor chip 30 is bonded onto the drain electrode layer 30a. As a result, the semiconductor chip 30 is fixed on the portion 100d of the lead frame 100. The drain of the semiconductor chip 30 is electrically connected to the portion 100d of the lead frame 100 via the drain electrode layer 30a and the bonding layer 31a.

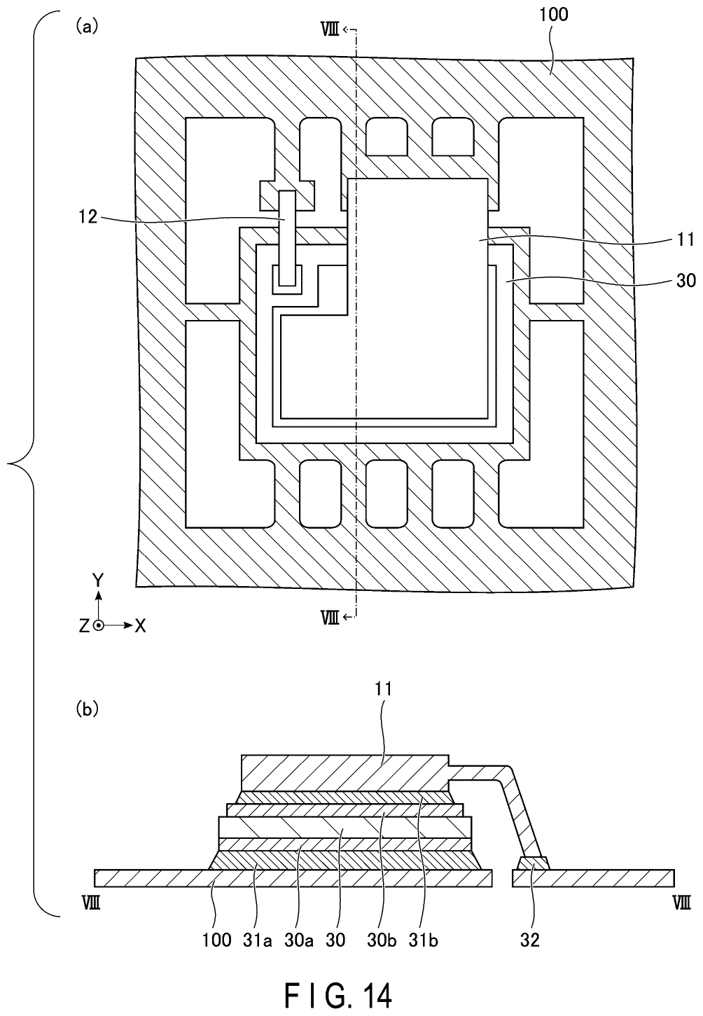

Next, as illustrated in FIGS. 11 and 14, the conductor layers 11 and 12 are bonded above the semiconductor chip 30 and above the lead frame 100 (S2). Specifically, the source electrode layer 30b and the bonding layer 31b, and the gate electrode layer 30c and the bonding layer 31c are formed on the semiconductor chip 30. The bonding layers 32 and 33 are formed on the lead frame 100. Further, the conductor layer 11 is bonded onto the bonding layers 31b and 32. Simultaneously or subsequently, the conductor layer 12 is bonded onto the bonding layers 31c and 33. As a result, the conductor layers 11 and 12 are fixed on the semiconductor chip 30 and the portions 100e and 100f of the lead frame 100. The source of the semiconductor chip 30 is electrically connected to the portion 100e of the lead frame 100 via the source electrode layer 30b, the bonding layer 31b, and the conductor layer 11. The gate of the semiconductor chip 30 is electrically connected to the portion 100f of the lead frame 100 via the gate electrode layer 30c, the bonding layer 31c, and the conductor layer 12.

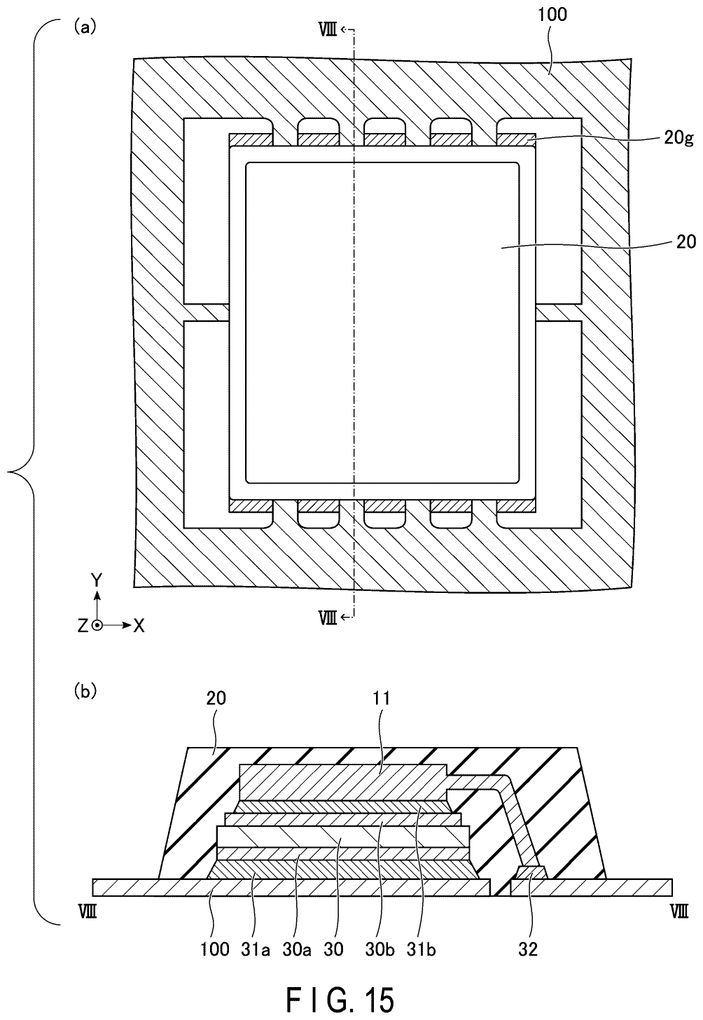

Next, as illustrated in FIGS. 11 and 15, the package 20 is formed around the semiconductor chip 30 on the lead frame 100 and around the conductor layers 11 and 12 (S3). Thus, the semiconductor chip 30 on the lead frame 100, and the conductor layers 11 and 12 are sealed by the package 20.

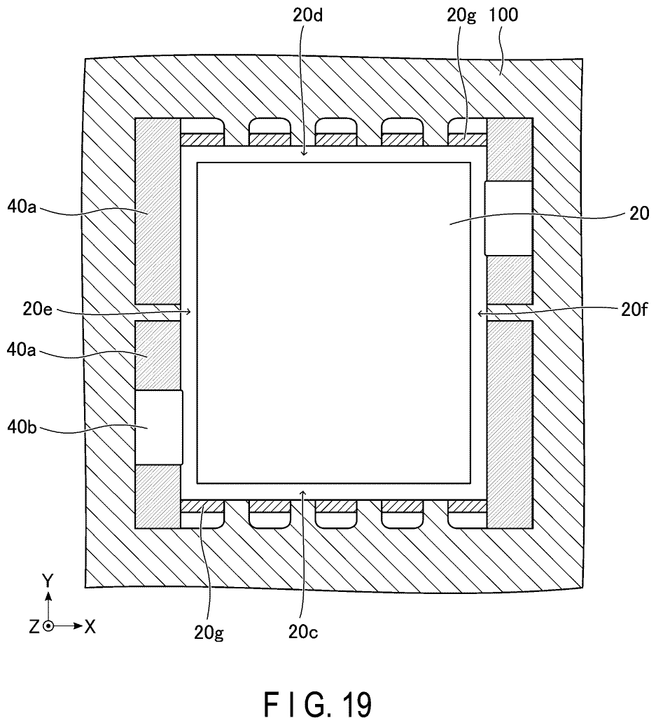

In the step of forming the package 20, for example, a resin sealing process is used, in which the package 20 is formed by resin molding by using a mold, and the package 20 seals the semiconductor chip 30 and the conductor layers 11 and 12. FIG. 19 illustrates the arrangement of a part of the mold in the resin sealing process.

The lead frame 100, the semiconductor chip 30, and the conductor layers 11 and 12 are sandwiched between two molds from below and above the lead frame 100, that is, in the Z direction. Hereinafter, the mold from below is referred to as a lower mold, and the mold from above is referred to as an upper mold.

The lead frame 100, the semiconductor chip 30, and the conductor layers 11 and 12 are sandwiched between the lower mold and the upper mold. Thereby, a space including the lead frame 100, the semiconductor chip 30, and the conductor layers 11 and 12 is formed. Molten resin is poured into the space, and the resin is solidified to form the package 20.

Here, as illustrated in FIG. 19, for example, the lower mold (alternatively, the upper mold) has a part (hereinafter, lead guide) 40a that is provided on the side surfaces 20e and 20f of the package 20 in the X direction. The side surfaces 20e and 20f of the package 20 are surfaces from which the lead terminals 10 do not protrude. Since the lead guide 40a is provided on the side surfaces 20e and 20f, the burrs 20g are not formed on the side surfaces 20e and 20f. The burrs 20g are a part of the resin forming the package 20, and are a resin molded to protrude from between the lower mold and the upper mold during molding the package 20. As described above, since the lead guide 40a is disposed on the side surfaces 20e and 20f, the resin does not protrude from between the lower mold and the upper mold, and no burrs are formed.

On the other hand, the lead guide is not provided on the side surfaces 20c and 20d of the package 20 in the Y direction. The side surfaces 20c and 20d of the package 20 in the Y direction are surfaces from which the lead terminals 10 protrude. Since no lead guide is provided on the side surfaces 20c and 20d, burr 20g is formed on the side surfaces 20c and 20d. The portion 40b where the lead guide does not present indicates an opening through which the resin flows during molding the package 20.

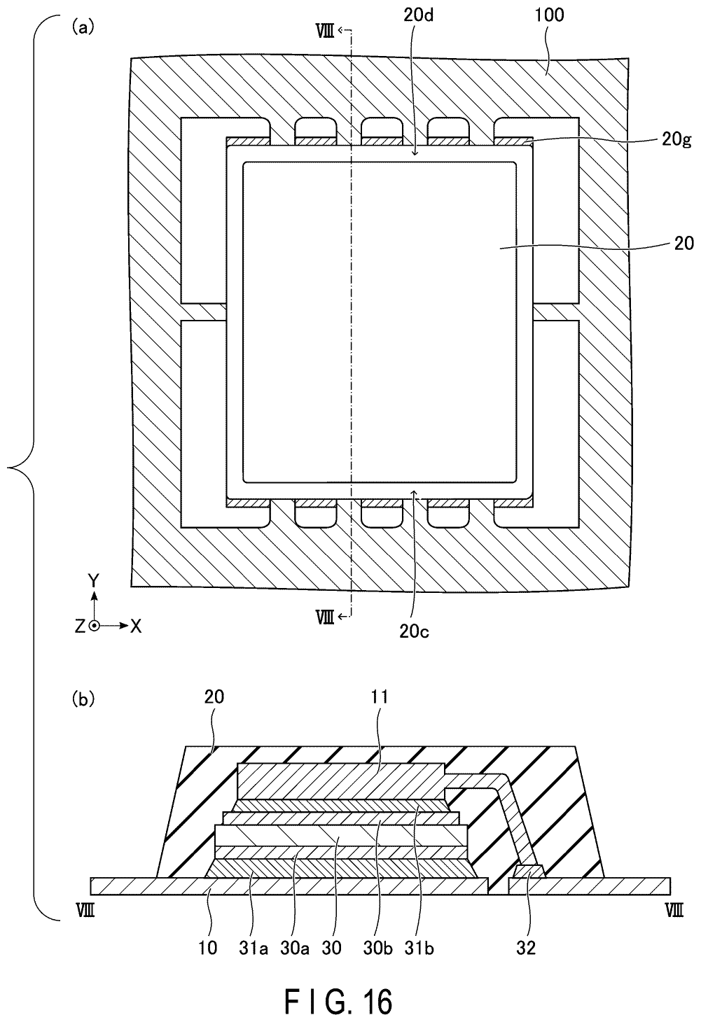

Next, as illustrated in FIGS. 11 and 16, the burrs 20g formed on the side surfaces 20c and 20d of the package 20 in the Y direction is removed by, for example, a laser (S4). In this step, the burrs cannot be completely removed from the side surfaces 20c and 20d of the package 20, and parts of the burrs 20g remain.

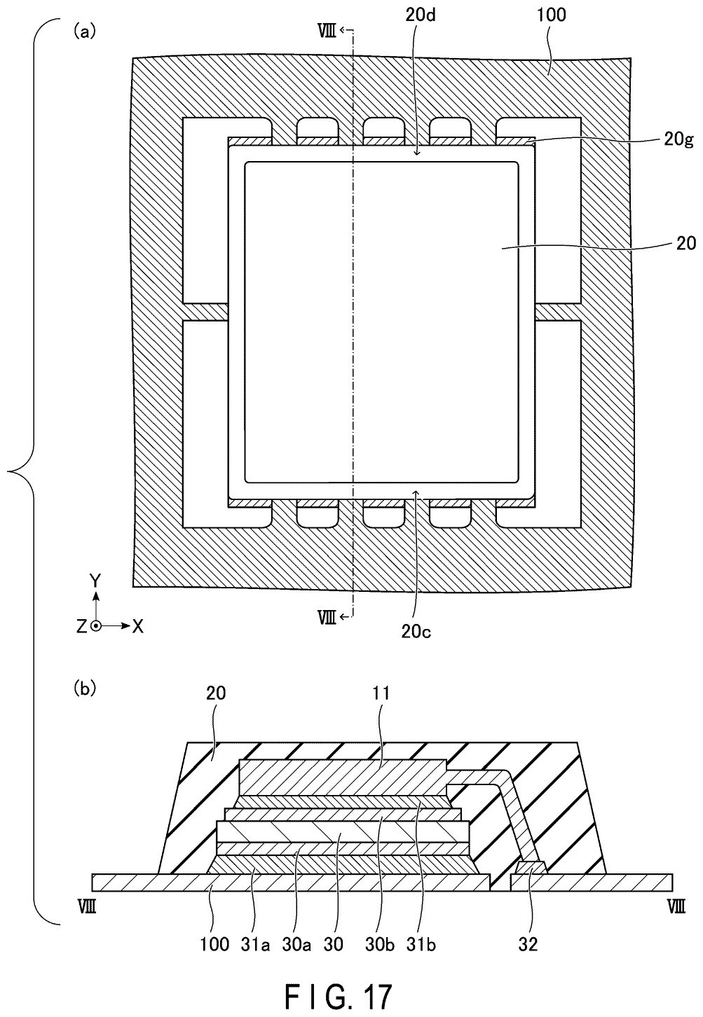

Next, as illustrated in FIGS. 11 and 17, the lead frame 100 serving as the lead terminal 10 is plated (S5). Examples of the plating material include a metal such as silver, gold, nickel, and palladium.

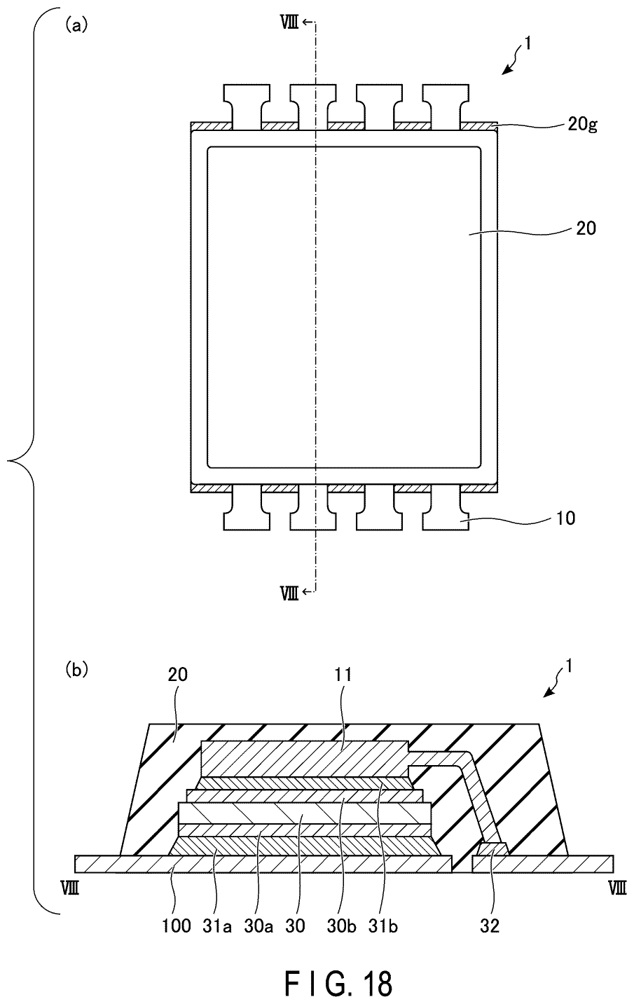

Thereafter, as illustrated in FIGS. 11 and 18, the continuous lead frames 100 are cut and singulated into individual semiconductor devices 1 (S6). Thus, the manufacturing process of the semiconductor device 1 is completed.

Next, the size of the specific portions in the semiconductor device 1 according to the embodiment will be described.

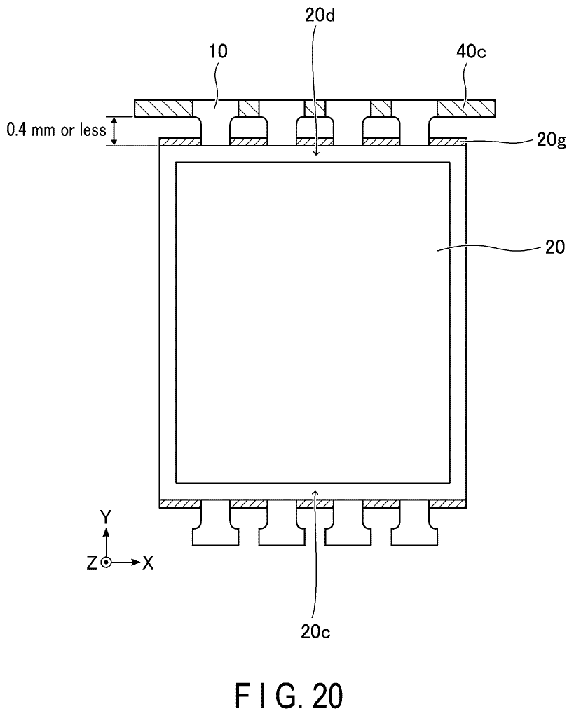

FIG. 20 is an upper surface view of the semiconductor device 1 according to the embodiment, illustrating the size of the package 20 and the lead terminal 10c.

The lead terminals 10 protrude from the side surface 20d of the package 20. Further, the burrs 20g are provided on the side surface 20d in a part of the surface from which the lead terminals 10 do not protrude, that is, between the lead terminals 10 and on both sides of the lead terminal 10 in the X direction.

Depending on the thickness of the lead terminal (alternatively, the lead frame) 10 in the Z direction, the distance required between the end of the side surface 20d and the end of the lead terminal 10 differs in order to secure the strength of the mold. A thick lead terminal 10 requires the distance to be long. A thin lead terminal 10 can make the distance short.

For example, if the thickness of the lead terminal 10 is 0.25 mm, as illustrated in FIG. 20, the distance between the end of the side surface 20d and the end of the lead terminal 10 can be set to 0.4 mm or less. Accordingly, the length of the lead terminal 10 can be shortened. If the thickness of the lead terminal is larger than 0.25 mm, there is little demand for shortening the length of the lead terminal 10, and there are many cases where the length of the lead terminal 10 is made longer to prioritize the energization capability. The region 40c indicates a region to be punched out with the mold in order to separate the lead terminals 10. The distance between the side surface 20c of the package 20 and the lead terminal 10 is also the same as described above.

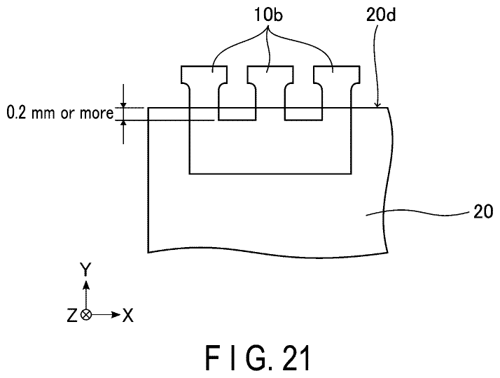

FIG. 21 is a view of a part of the semiconductor device 1 according to the embodiment as viewed from below (that is, from the lower surface of the package 20), and illustrates the size of the package 20 and the lead terminals 10b. FIG. 21 is a view of the package 20 as seen through, illustrating the lead frame including the lead terminals 10b and the side surface 20d of the package 20 including the burrs 20g.

For example, if the thickness of the lead terminal (alternatively, the lead frame) 10b in the Z direction is 0.25 mm, as illustrated in FIG. 21, the distance between the end of the package 20 (alternatively, the end of the side surface 20d) and the end of the lead frame in the package 20 is set to 0.2 mm or more. By setting the distance to 0.2 mm or more, the end of the lead frame can be easily filled with the resin.

As described above, according to the embodiment, the lead guide (that is, a part of the mold) is not provided on the side surfaces (that is, the side surface from which the lead terminals 10 protrude) 20c and 20d of the package 20 in the Y direction, and the lead guide is provided on the side surfaces (that is, the side surface from which the lead terminals 10 do not protrude) 20e and 20f of the package 20 in the X direction. As a result, the lead terminals 10 provided on the side surfaces 20c and 20d in the Y direction can be shortened, that is, the length from the side surface of the package 20 to the tip of the lead terminals 10 can be shortened. Furthermore, the burrs provided on the side surfaces 20e and 20f of the package 20 can be reduced.

For example, in a case where the package 20 is formed by providing the lead guide, it is necessary to set the lead guide to a certain size or more in order to secure the strength of the lead guide. Therefore, the shortest length of the lead terminal is determined by the size of the lead guide. However, if the package 20 is formed without providing the lead guide, it is not necessary to secure a region for providing the lead guide, so that the length of the lead terminal 10 can be shortened.

In the embodiment, the lead guide is provided on the side surfaces 20e and 20f, from which the lead terminals 10 do not protrude. Thereby, the burrs formed on the side surfaces 20e and 20f of the package 20 can be reduced. This makes it possible to reduce the number of man-hours for removing the burrs in the manufacturing process.

In the embodiment, the lead guide is not provided on the side surfaces 20c and 20d, from which the lead terminals 10 protrude. Thereby, the package 20 can be formed even if the interval between the lead terminals is narrow. That is, the package 20 can be molded even in a product specification in which the lead terminals have a narrow pitch (alternatively, narrow size) therebetween such that a lead guide cannot be disposed between the lead terminal and the lead terminal adjacent thereto.

As described above, according to the embodiment, the lead terminals 10 can be shortened, and the burrs provided on the package 20 can be reduced.

### 2. MODIFICATION

Next, a semiconductor device 1 according to a modification of the embodiment will be described. In the modification, the shape of the side surfaces 20e and 20f of the package 20 is different from the shape illustrated in FIG. 4. In the modification, points different from the above-described embodiment will be mainly described.

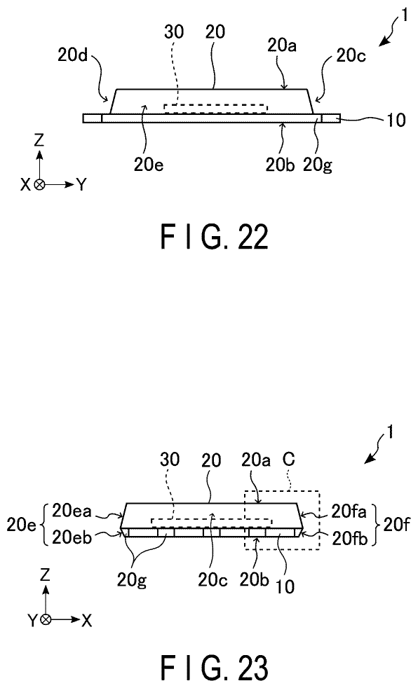

FIG. 22 is a side surface view of the semiconductor device 1 according to the modification as viewed from the X direction. FIG. 23 is a side surface view of the semiconductor device 1 according to the modification as viewed from the Y direction.

As illustrated in FIG. 23, the side surface 20e of the package 20 has a surface 20ea and a surface 20eb. The surfaces 20ea and 20eb form a chevron shape between the upper surface 20a and the lower surface 20b of the package 20.

Similarly, the side surface 20f of the package 20 has a surface 20fa and a surface 20fb. The surfaces 20fa and 20fb form a chevron shape between the upper surface 20a and the lower surface 20b of the package 20. The side surfaces 20c and 20d of the package 20 are similar to those of the above-described embodiment.

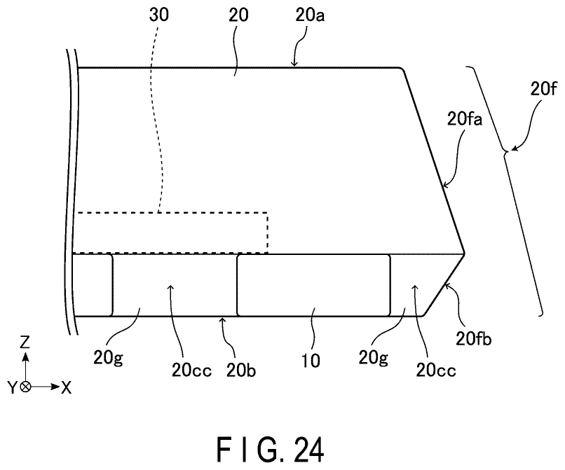

Next, details of the side surfaces 20e and 20f of the package 20 will be described. FIG. 24 is an enlarged view of the portion C in the semiconductor device 1 illustrated in FIG. 23, and illustrates the detailed structure of the side surface 20f. Since the structure of the side surface 20e is similar to that of the side surface 20f, description thereof is omitted.

As described above, the side surface 20f of the package 20 has the surface 20fa and the surface 20fb. The surface 20fa is continuous with the upper surface 20a of the package 20 and is provided in a first oblique direction with respect to the upper surface 20a of the package 20. The surface 20fb is continuous with the surface 20fa and is provided in a second oblique direction different from the first oblique direction with respect to the upper surface 20a of the package 20.

In other words, viewed from the Y direction (alternatively, the side surface 20c side), the surface 20fa is provided in a right-downward oblique direction with respect to the upper surface 20a of the package 20 from the upper surface 20a of the package 20 to the position of the upper surface (alternatively, the height) of the lead terminal 10 (alternatively, burr 20g). The surface 20fb is provided in a right-upward oblique direction with respect to the upper surface 20a of the package 20 from the position of the upper surface of the lead terminal 10 to the lower surface 20b of the package 20.

Similarly, viewed from the Y direction (alternatively, the side surface 20c side), the surface 20ea is provided in a right-upward oblique direction with respect to the upper surface 20a of the package 20 from the upper surface 20a of the package 20 to the position of the upper surface (alternatively, the height) of the lead terminal 10 (alternatively, burr 20g). The surface 20eb is provided in a right-downward oblique direction with respect to the upper surface 20a of the package 20 from the position of the upper surface of the lead terminal 10 to the lower surface 20b of the package 20.

### 3. OTHERS

In the above-described embodiment and modification, an example in which the semiconductor chip 30 includes a MOS field-effect transistor (that is, MOSFET) has been described, but the semiconductor chip 30 may include an active element such as an insulated gate bipolar transistor (IGBT) or a diode. The number and shape of the lead terminals and members included in the semiconductor device 1 can be appropriately changed according to the elements included in the semiconductor chip 30.

In the present specification, the term “connection” indicates that a plurality of members (alternatively, elements) is directly connected or that a plurality of members is electrically connected. For example, it is not excluded that another member is interposed between two connected members.

While certain embodiments have been described, these embodiments have been presented by way of example only, and are not intended to limit the scope of the inventions. Indeed, the novel embodiments described herein may be embodied in a variety of other forms; further, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a lead frame;
a semiconductor chip provided above the lead frame;
a first lead terminal electrically connected to the semiconductor chip; and
a package encapsulating the semiconductor chip, a part of the lead frame, and a part of the first lead terminal;
wherein
the package includes an upper surface, a lower surface, a first side surface, and a second side surface:
the upper surface is provided above the semiconductor chip;
the lower surface is provided below the semiconductor chip;
the first side surface is provided between the upper surface and the lower surface, and the first lead terminal protrudes from the first side surface;
the first side surface has a first surface, a second surface, and a third surface:
the first surface is continuous with the upper surface of the package and is provided in an oblique direction with respect to the upper surface of the package,
the second surface is continuous with the first surface and is provided in a direction parallel to the upper surface of the package, and
the third surface is continuous with the second surface and is provided in a direction orthogonal to the upper surface of the package; and
the second side surface is provided between the upper surface and the lower surface, and the first lead terminal does not protrude from the second side surface.

2. The semiconductor device according to claim 1, wherein
the package includes a first portion protruding on the first side surface and provided adjacent to the first lead terminal, and
an upper surface of the first portion corresponds to the second surface, and a side surface of the first portion corresponds to the third surface.

3. The semiconductor device according to claim 1, wherein
a position of the second surface of the first side surface coincides with a position of an upper surface of the first lead terminal in a direction orthogonal to the upper surface of the package.

4. The semiconductor device according to claim 1, wherein
a distance from the lower surface of the package to the second surface of the first side surface coincides with a distance from the lower surface of the package to an upper surface of the first lead terminal.

5. The semiconductor device according to claim 2, further comprising:
a plurality of lead terminals including the first lead terminal;
wherein
the lead terminals are arranged at intervals on the first side surface, and
the first portion is provided between the lead terminals.

6. The semiconductor device according to claim 2, further comprising:
a plurality of lead terminals including the first lead terminal;
wherein
the lead terminals are arranged at intervals on the first side surface in a direction parallel to the upper surface of the package, and
the first portion is provided between the lead terminals, and outside a lead terminal disposed at a most end portion among the arranged lead terminals.

7. The semiconductor device according to claim 1, wherein
the second side surface is provided in an oblique direction with respect to the upper surface of the package.

8. The semiconductor device according to claim 2, wherein
the second side surface is,
in a direction orthogonal to the upper surface of the package, provided in a first oblique direction with respect to the upper surface of the package from the upper surface of the package to a position of an upper surface of the first portion, and
provided in a second oblique direction different from the first oblique direction with respect to the upper surface of the package from a position of the upper surface of the first portion to the lower surface of the package.

9. The semiconductor device according to claim 1, further comprising:
a second lead terminal electrically connected to the semiconductor chip;
Wherein
the package includes a third side surface and a fourth side surface:
the third side surface is provided between the upper surface and the lower surface of the package, and the second lead terminal protrudes from the third side surface;
the third side surface has a fourth surface, a fifth surface, and a sixth surface:
the fourth surface is continuous with the upper surface of the package and is provided in an oblique direction with respect to the upper surface of the package,
the fifth surface is continuous with the fourth surface and is provided in a direction parallel to the upper surface of the package, and
the sixth surface is continuous with the fifth surface and is provided in a direction orthogonal to the upper surface of the package; and
the fourth side surface is provided between the upper surface and the lower surface, and the second lead terminal does not protrude from the fourth side surface.

10. The semiconductor device according to claim 9, wherein
the package includes a second portion protruding on the third side surface and provided adjacent to the second lead terminal, and
an upper surface of the second portion corresponds to the fifth surface, and a side surface of the second portion corresponds to the sixth surface.

11. The semiconductor device according to claim 9, wherein
the fourth side surface is provided in an oblique direction with respect to the upper surface of the package.

12. The semiconductor device according to claim 10, wherein
the fourth side surface is,
in a direction orthogonal to the upper surface of the package, provided in a first oblique direction with respect to the upper surface of the package from the upper surface of the package to a position of an upper surface of the second portion, and
provided in a second oblique direction different from the first oblique direction with respect to the upper surface of the package from a position of the upper surface of the second portion to the lower surface of the package.

13. The semiconductor device according to claim 9, wherein
the third side surface is disposed to face the first side surface, and the fourth side surface is disposed to face the second side surface.

14. The semiconductor device according to claim 1, wherein
the package seals the semiconductor chip on the lead frame.

15. The semiconductor device according to claim 2, wherein
the package and the first portion of the package include a resin.

16. A method of manufacturing a semiconductor device comprising:
placing a semiconductor chip above a lead frame;
providing a conductor layer that connects the lead frame and the semiconductor chip; and
forming a package encapsulating the semiconductor chip and the conductor layer by using a mold, wherein
in the forming the package, the package includes: an upper surface provided above the semiconductor chip; a lower surface provided below the semiconductor chip; a first side surface provided between the upper surface and the lower surface, and protruding the lead frame; and a second side surface provided between the upper surface and the lower surface, and not protruding the lead frame, and
the package is formed while a part of the mold is disposed on the second side surface of the package, and a part of the mold is not disposed on the first side surface of the package.

17. The method of manufacturing the semiconductor device according to claim 16, further comprising:
plating the lead frame after forming the package; and
cutting and singulating the lead frame to obtain the semiconductor device after plating the lead frame.

18. The method of manufacturing the semiconductor device according to claim 17, further comprising:
removing a burr formed on the first side surface of the package after forming the package and before plating the lead frame.
